(19) United States
(12) Patent Application Publication
(10) Pub. No.: US 2019/0237695 A1
(43) Pub. Date: Aug. 1, 2019

(54) OLED DISPLAY PANEL, DISPLAY DEVICE AND MANUFACTURING METHOD OF OLED DISPLAY PANEL

(71) Applicant: BOE TECHNOLOGY GROUP CO., LTD., Beijing (CN)

(72) Inventor: Shiming SHI, Beijing (CN)

(21) Appl. No.: 16/114,278

(22) Filed: Aug. 28, 2018

(30) Foreign Application Priority Data
Jan. 31, 2018 (CN) 201810097762.6

(51) Int. Cl. H01L 51/52; G09G 3/3208; H01L 51/56; H01L 27/32

(52) U.S. Cl. CPC H01L 51/5203; G09G 3/3208; H01L 27/3276; H01L 51/524; H01L 51/56

(57) ABSTRACT

The present disclosure relates to the field of display technology, and discloses an OLED display panel, a display device and a manufacturing method of an OLED display panel. The OLED display panel includes a base substrate and a plurality of pixel units disposed on the base substrate. At least one pixel unit includes an organic electroluminescent device and an auxiliary electrode layer, in which the organic electroluminescent device includes an organic light-emitting layer and an top electrode layer arranged to be sequentially stacked on the base substrate, and in which the auxiliary electrode layer is located at a side of the top electrode layer away from the base substrate and connected with the top electrode layer in parallel.

### CROSS-REFERENCE TO RELATED APPLICATIONS

The present application is based on and claims priority to Chinese Patent Application No. 201810097762.6, filed on Jan. 31, 2018, the entire contents thereof are incorporated herein by reference.

### TECHNICAL FIELD

The present disclosure relates to the field of display technology, in particular to an OLED display panel, a display device and a manufacturing method of an OLED display panel.

### BACKGROUND

Active-Matrix Organic Light Emitting Diode (OLED) display panel has been used in the field of flexible display. A bottom emission typed organic electroluminescent device cannot be used on the display panel as a flexible substrate of the display panel is yellowish when a large-sized OLED display panel is developed, therefore a top emission typed organic electroluminescent device is required. In addition, in order to increase the aperture ratio of an organic electroluminescent device of the display panel with high resolution, the top emission typed organic electroluminescent device is also required.

A translucent or transparent top electrode is required in the top emission typed organic electroluminescent device, in which a resistance of this top electrode is usually large. For example, a square resistance of Mg/Ag composite metal electrode is about 15˜30Ω□, while a square resistance of ITO (Indium Tin Oxides) or IZO (Indium Zinc Oxides) is 30Ω/□. The organic electroluminescent device is a current-typed device, brightness of which is higher with larger current to be required. When the resistance of the top electrode is larger, it causes a larger pressure drop at the top electrode. Therefore, in the design for the drive of the OLED display panel, it is necessary to increase a driving voltage of the top electrode in order to compensate for the pressure drop of the top electrode, thereby resulting in an increase in power consumption of the product. Moreover, the difference in display brightness is also caused by inconsistent driving voltage within the display region, thereby causing homogeneity of the picture to be reduced.

### SUMMARY

According to an aspect of the present disclosure, an embodiment of the present disclosure provides an OLED display panel including a base substrate and a plurality of pixel units, the plurality of pixel units being disposed on the base substrate, at least one pixel unit including an organic electroluminescent device and an auxiliary electrode layer, the organic electroluminescent device including an organic light-emitting layer and an top electrode layer arranged to be sequentially stacked on the base substrate, the auxiliary electrode layer being located at a side of the top electrode layer away from the base substrate and connected with the top electrode layer in parallel.

According to an embodiment of the present disclosure, a top electrode signal line is provided on the base substrate, and the top electrode layer is connected with the top electrode signal line, the auxiliary electrode layer is connected with the top electrode signal line.

According to an embodiment of the present disclosure, at least one first packaging layer is provided between the auxiliary electrode layer and the top electrode layer.

According to an embodiment of the present disclosure, at least one via hole is provided on the at least one first packaging layer, and the auxiliary electrode layer is connected with the top electrode layer by a conductor disposed within the at least one via hole.

According to an embodiment of the present disclosure, a protective layer disposed at a side of the top electrode layer away from the base substrate is also included, in which a pattern of the protective layer is located between the top electrode layer and the conductor within the at least one via hole.

According to an embodiment of the present disclosure, the pattern of the protective layer includes at least one strip electrode, each of which is correspondingly connected with the conductor within at least one via hole; alternatively,

the pattern of the protective layer includes at least one block electrode, each of which is correspondingly connected with the conductor within a via hole;

the protective layer is made of aluminum, indium tin oxide or zinc tin oxide.

According to an embodiment of the present disclosure, a via hole is provided on the at least one first packaging layer, and the auxiliary electrode layer is connected with the top electrode signal line by the conductor disposed within the via hole.

According to an embodiment of the present disclosure, the at least one first packaging layer includes at least one organic film layer, or alternatively, the at least one first packaging layer includes at least one inorganic film layer, or alternatively, the at least one first packaging layer includes at least one organic film layer and at least one inorganic film layer arranged to be sequentially overlapped.

According to an embodiment of the present disclosure, at least one second packaging layer is provided at a side of the auxiliary electrode layer away from the base substrate;

the at least one second packaging layer includes at least one organic film layer, or alternatively, the at least one second packaging layer includes at least one inorganic film layer, or alternatively, the at least one second packaging layer includes at least one organic film layer and at least one inorganic film layer arranged to be sequentially overlapped.

According to an embodiment of the present disclosure, a first packaging layer is provided between the auxiliary electrode layer and the top electrode layer, two second packaging layers are provided at a side of the auxiliary electrode layer away from the base substrate;

the first packaging layer is an inorganic film layer;

in these two second packaging layers, one of the second packaging layers adjacent to a side of the auxiliary electrode layer is an organic film layer or an organic/inorganic composite film layer, while one of second packaging layers away from the side of the auxiliary electrode layer is an inorganic film layer.

According to an embodiment of the present disclosure, the auxiliary electrode layer is connected with the top electrode signal line by a conductive wire disposed on the at least one first packaging layer.

According to an embodiment of the present disclosure, at least one first packaging layer is provided between the auxiliary electrode layer and the top electrode layer, and at least two via holes are provided in the first packaging layer, the auxiliary electrode layer being connected with the top electrode layer by a conductor disposed within the at least two via holes.

According to an embodiment of the present disclosure, an orthographic projection of the pattern of the auxiliary electrode layer on the base substrate is located in a non-lighting region.

According to an embodiment of the present disclosure, an orthographic projection of the pattern of the auxiliary electrode layer on the base substrate is located between orthographic projections of adjacent organic electroluminescent devices on the base substrate.

According to an embodiment of the present disclosure, in a pixel unit including an organic electroluminescent device and an auxiliary electrode layer, an orthographic projection of the auxiliary electrode layer on the base substrate surrounds an orthographic projection of the organic electroluminescent device on the base substrate.

According to an embodiment of the present disclosure, a thickness of the auxiliary electrode layer is greater than that of the top electrode layer.

The present disclosure further provides a display device including the OLED display panel provided by the above technical solutions, the display panel including: a base substrate and a plurality of pixel units, the plurality of pixel units being disposed on the base substrate, at least one pixel unit including an organic electroluminescent device and an auxiliary electrode layer, the organic electroluminescent device including an organic light-emitting layer and a top electrode layer arranged to be sequentially stacked on the base substrate, the auxiliary electrode layer being located at a side of the top electrode layer away from the base substrate and connected with the top electrode layer.

The present disclosure further provides a manufacturing method of an OLED display panel, the OLED display panel including:

a base substrate;

a plurality of pixel units disposed on the base substrate;

at least one of pixel units including:

an organic electroluminescent device including an organic light-emitting layer and a top electrode layer arranged to be sequentially stacked on the base substrate;

an auxiliary electrode layer disposed at a side of the top electrode layer away from the base substrate, and connected with the top electrode layer in parallel;

at least one first packaging layer being provided between the auxiliary electrode layer and the top electrode layer; at least one via hole being provided in the first packaging layer, the specific manufacturing process of which is as follows:

disposing the organic light-emitting layer, the top electrode layer and the at least one first packaging layer on the base substrate, sequentially;

etching the at least one first packaging layer to form a via hole penetrating through the at least one packaging layer from up to down; and

filling a conductor material into the via hole.

According to an embodiment of the present disclosure, a protective layer is disposed between the top electrode layer and the at least one packaging layer to prevent etchants from damaging the top electrode layer.

### BRIEF DESCRIPTION OF THE DRAWINGS

FIG. 1 is a cross-sectional structural view of an OLED display panel according to an embodiment of the present disclosure;

FIG. 2 is a cross-sectional structural view of an OLED display panel according to an embodiment of the present disclosure;

FIG. 3 is a cross-sectional structural view of an OLED display panel according to an embodiment of the present disclosure;

FIG. 4 is a structural view of an OLED display panel according to an embodiment of the present disclosure;

FIG. 5 is a structural view of a pixel unit in an OLED display panel according to an embodiment of the present disclosure; and

FIG. 6 is a flowchart of a manufacturing method of an OLED display panel according to an embodiment of the present disclosure.

### DETAILED DESCRIPTION

Technical solutions in the embodiments of the present disclosure will be clearly and completely described in the following with reference to the accompanying drawings in the embodiments of the present disclosure. It is obvious that the described embodiments are only a part of the embodiments of the present disclosure, but not all of the embodiments. Based on the embodiments of the present disclosure, all other embodiments obtained by those ordinary skilled in the art without any creative work belong to the scope of the present disclosure.

According to an aspect of the present disclosure, an embodiment of the present disclosure provides an OLED display panel for solving problems such as increased product power consumption and reduced display uniformity due to larger top electrode resistance of the organic electroluminescent device in the existing organic electroluminescent display panel.

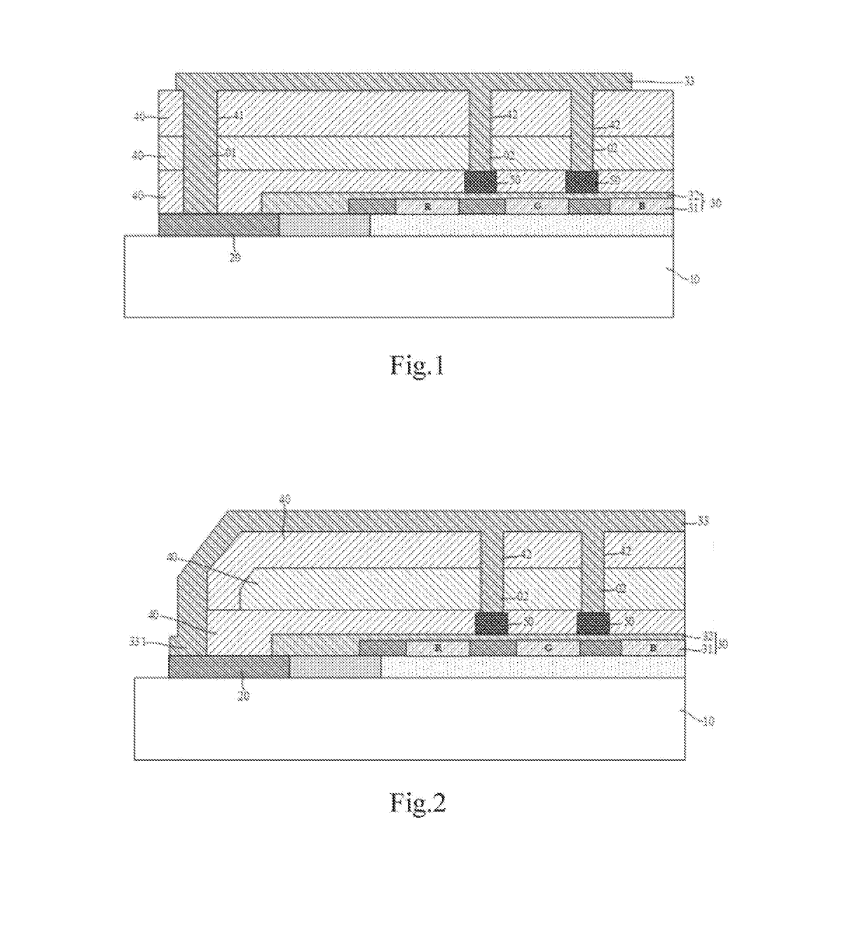

As shown in FIG. 1, an OLED display panel provided by an embodiment of the present disclosure includes a base substrate 10 and a plurality of pixel units disposed on the base substrate 10. An organic electroluminescent device 30 and an auxiliary electrode layer 33 are included in at least one pixel unit. The organic electroluminescent device 30 includes an organic light-emitting layer 31 and a top electrode layer 32 arranged to be sequentially stacked on the base substrate 10, and the auxiliary electrode layer 33 is located at a side of the top electrode layer 32 away from the base substrate 10 and connected with the top electrode layer 32 in parallel. The pixel unit may be any one of three single-color sub-pixels of R, G and B.

In a specific implementation, the base substrate 10 may be a flexible substrate or a non-flexible substrate; in each of organic electroluminescent devices 30, the top electrode layer 32 may be manufactured by using an evaporation method, and the material thereof may be aluminum, silver, indium tin oxide or zinc oxide tin or the like; the base substrate has a display region and a non-display region, the plurality of organic electroluminescent devices 30 are located in an effective display region on the base substrate 10.

It should be noted that, in a specific implementation, the top electrode layer 32 may be a cathode layer or an anode layer depending on the arrangement of the structure of organic electroluminescent devices. Specifically, when the organic electroluminescent device is an upright type organic electroluminescent device, the top electrode layer 32 is a cathode layer; and when the organic electroluminescent device is an inverted type organic electroluminescent device, the top electrode layer 32 is an anode layer.

In a specific implementation, the connection manner of the auxiliary electrode layer 33 and the top electrode layer 32 can be seen in FIG. 1. The top substrate signal line 20 is disposed on the base substrate 10, and is used to transmit a driving signal to the top electrode layer 32. One end of the top electrode layer 32 is connected with the top electrode signal line 20, and one end of the auxiliary electrode layer 33 is connected with the top electrode signal line 20. As shown in FIG. 1, the auxiliary electrode layer 33 and the top electrode layer 32 are connected in parallel to a drive circuit.

In a specific implementation, the top electrode signal line 20 is located in a peripheral circuit region.

In the OLED panel shown in FIG. 1, the top electrode layer 32 and the auxiliary electrode layer 33 are connected in parallel to a power supply circuit of the top electrode signal line 20, which corresponds to connecting a resistance in parallel to the resistance of the top electrode layer 32 itself, thereby reducing the resistance of the top electrode layer 32. In order to further reduce the parallel resistance of the top electrode layer 32 and the auxiliary electrode layer 33, in a specific implementation, a thickness of the auxiliary electrode layer 33 is greater than a thickness of the top electrode layer 32, so that the resistance of the auxiliary electrode layer 33 is smaller than that of the top electrode layer 32, which may in turn reduce the parallel resistance of them. Specifically, the auxiliary electrode layer 33 is made of at least one of molybdenum, aluminum, titanium or neodymium, and the auxiliary electrode layer 33 may be a single metal layer or a multilayer composite metal layer.

In order to separate the top electrode layer 32 from the auxiliary electrode layer 33 and improve the sealing effect on the organic light-emitting layer 31 in the organic electroluminescent device 30, as shown in FIG. 1, in a specific implementation, three first packaging layers 40 are disposed between the auxiliary electrode layer 33 and the top electrode layer 32. In a specific implementation, the number of the first packaging layers 40 should be at least one, and may be set as other numbers such as two, four and the like, according to the required sealing performance requirements. The first packaging layer 40 may be made of an inorganic material, such as silicon nitride, silicon oxide, silicon oxynitride, silicon carbon nitride, aluminum oxide, etc., and may also be made of an organic material or an organic/inorganic composite material. Specifically, the first packaging layer 40 can be fabricated by an atomic layer deposition process to form a film layer having a low thickness and a denser density.

When the first packaging layer 40 is disposed between the top electrode layer 32 and the auxiliary electrode layer 33, in order to connect the top electrode layer 32 and the auxiliary electrode layer 33, as shown in FIG. 1, in a specific implementation, two via holes 42 are provided on these three first packaging layers 40, and the auxiliary electrode layer 33 and the top electrode layer 32 are connected by a conductor 02 disposed within two via holes 42. In one implementation, the number of via holes 42 for connecting the top electrode layer 32 and the auxiliary electrode layer 33 is at least one, and may be set as other numbers such as three, four, five and the like.

When via holes on the first packaging layer 40 are manufactured, the first packaging layer 40 is generally etched by etching, in order to improve erosion on the top electrode layer 32 under the first packaging layer 40 in the etching process, as shown in FIG. 1, in one implementation, a protective layer 50 disposed at a side of the top electrode layer 32 away from the substrate 10 is further included, the pattern of which is located between the top electrode layer 32 and the conductor 02 within at least one via hole 42. The pattern of the protective layer 50 serves to protect the top electrode layer 32 during the etching process of via holes 42. Specifically, the pattern of the protective layer 50 can be as shown in FIG. 1. The pattern of the protective layer 50 includes two block electrodes, each of which is correspondingly connected to the conductor 02 within one via hole 42. In a specific implementation, the number of block electrodes should be set in one-to-one correspondence according to the number of via holes 42 in the packaging layer 40, and an area of each of block electrodes should be larger than that of the corresponding via hole 42 to improve protection of the top electrode layer 32. In addition, in other implementations, the pattern of the protective layer 50 may take other shapes. Specifically, the pattern of the protective layer 50 includes at least one strip electrode, and each strip electrode is correspondingly connected with the conductor 02 within the at least one via hole 42. Thus, each strip electrode can be arranged to correspond to one or more via holes 42.

Specifically, in each of organic electroluminescent devices 30, the protective layer 50 is made of a material including aluminum, indium tin oxide or zinc tin oxide, and a manufacturing process thereof can be carried out by an evaporation method.

Corresponding to the connection manner of the top electrode layer 32 and the auxiliary electrode layer 33, the auxiliary electrode layer 33 and the top electrode signal line 20 may also be connected through the via holes within the first packaging layer 40. Since an organic electroluminescent device 30 adjacent to the top electrode signal line 20 is connected to the top electrode signal lines 20 in a plurality of the organic electroluminescent devices 30, referring to FIG. 1, in one implementation, the first packaging layer 40 is provided with a via hole 41, and the auxiliary electrode layer 33 and the top electrode signal line 20 are connected by a conductor 01 provided within the via hole 41.

In other implementations, the top electrode signal line 20 and the auxiliary electrode layer 33 may also be connected without via holes to reduce the number of via holes and simplify the manufacturing process. Referring to FIG. 2, in a specific implementation, the auxiliary electrode layer 33 and the top electrode signal line 20 are connected by a conductive wire 331 provided on the packaging layer 40. In this embodiment, the conductive wire 331 is a part of the auxiliary electrode layer 33 itself, and can be manufactured by an evaporation process.

In an implementation, the parallel connection manner of the top electrode layer 32 and the auxiliary electrode layer 33 is different from that of the above embodiment, i.e. two top electrode signal lines 20 are provided on the base substrate 10, both ends of the top electrode layer 32 are respectively connected with different top electrode signal lines 20, and both ends of the auxiliary electrode layer 33 are respectively connected with different top electrode signal lines 20. That is, the parallel connection of the top electrode layer 32 and the auxiliary electrode layer 33 is realized by the top electrode signal line 20.

In an implementation, at least one first packaging layer 40 is disposed between the auxiliary electrode layer 33 and the top electrode layer 32, at least two via holes 42 are provided in the first packaging layer 40, and the auxiliary electrode layer 33 and the top electrode layer 32 are connected by a conductor provided within the via hole 43. For example, in order to realize the parallel connection of the auxiliary electrode layer 33 and the top electrode layer 32, one end of the auxiliary electrode layer 33 and the top electrode layer 32 is respectively connected to the conductor within one via hole, and the other end of the auxiliary electrode layer 33 and the top electrode layer 32 is respectively connected to the conductor with another via hole. That is, the parallel connection of the auxiliary electrode layer 33 and the top electrode layer 32 is realized only by the conductor within the via hole 42, which is different from the parallel connection of the auxiliary electrode layer 33 and the top electrode layer 32 realized by the top electrode signal line 20 in the above embodiment.

An orthographic projection of the pattern of the auxiliary electrode layer 33 on the base substrate 1 is located in the non-lighting region. Specifically, the pattern of the auxiliary electrode layer 33 may be disposed within an effective display region or within a peripheral circuit region.

When the auxiliary electrode layer 33 is disposed within the effective display region, as the auxiliary electrode layer 33 is disposed at the side of the organic light-emitting layer 31 away from the substrate 10, it is possible to block part of the light emitted from the organic light-emitting layer 31. In order to reduce blocking of the light emitted from the organic light-emitting layer 31 by the auxiliary electrode layer 33, the orthographic projection of the pattern of the auxiliary electrode layer 33 on the organic light-emitting layer 31 is located within the non-lighting region of the organic electroluminescent device 30 to reduce blocking of the light emitted from the organic light-emitting layer 31 by the auxiliary electrode layer 33. Specifically, the non-lighting region of the organic electroluminescent device 30 includes a peripheral region of the organic light-emitting layer 31, specifically, for example, a peripheral region between two adjacent organic electroluminescent devices and a peripheral region of the pixel-interposing layer. The non-lighting region further includes a partial region of the organic light-emitting layer blocked by a driving device such as a thin film transistor. Referring to FIG. 4, in a specific implementation, the orthographic projection of the pattern of the auxiliary electrode layer 33 on the base substrate 10 is located between orthographic projections of the adjacent organic electroluminescent devices 311 on the base substrate to avoid the light-emitting region of the organic light-emitting layer. In a specific implementation, the orthographic projections of the patterns of two auxiliary electrode layers 33 of two adjacent pixel units on the base substrate 10 may be disposed between orthographic projections of the corresponding adjacent two organic electroluminescent devices on the base substrate. The patterns of auxiliary electrode layers 33 of the plurality of pixel units may also be arranged as shown in FIG. 4. When the plurality of pixel units are distributed in an array, the patterns of auxiliary electrode layers 33 are arranged to be intersected between the pixel units. Then, the periphery of each pixel unit is surrounded by a pattern of the auxiliary electrode layer 33. In addition, as shown in FIG. 5, the pattern of the auxiliary electrode layer 33 may also be disposed in a ring shape, and the orthographic projection of the pattern of the auxiliary electrode layer 33 on the base substrate is disposed to surround the orthographic projection of the corresponding organic electroluminescent device 311 on the base substrate. In other implementations, a wiring density of the pattern of the auxiliary electrode layer 33 may also be reduced to reduce blocking of the light of the organic light-emitting layer caused by the auxiliary electrode layer. Specifically, it may be implemented in such a way that two or more organic electroluminescent devices may share one auxiliary electrode layer.

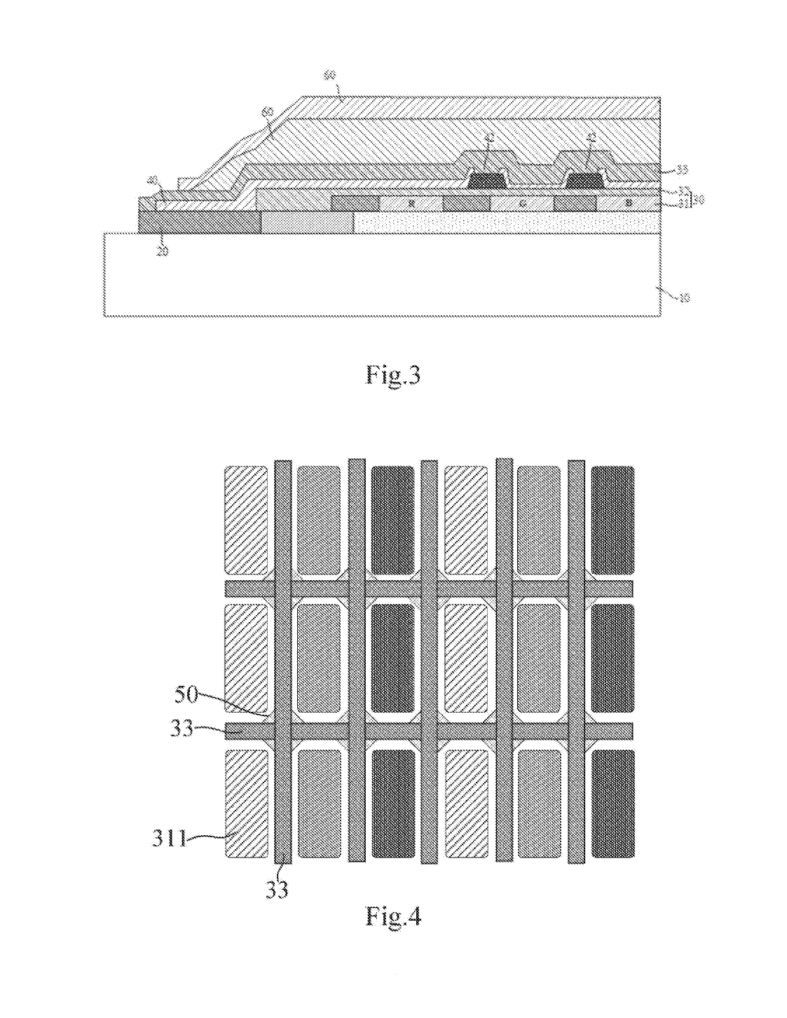

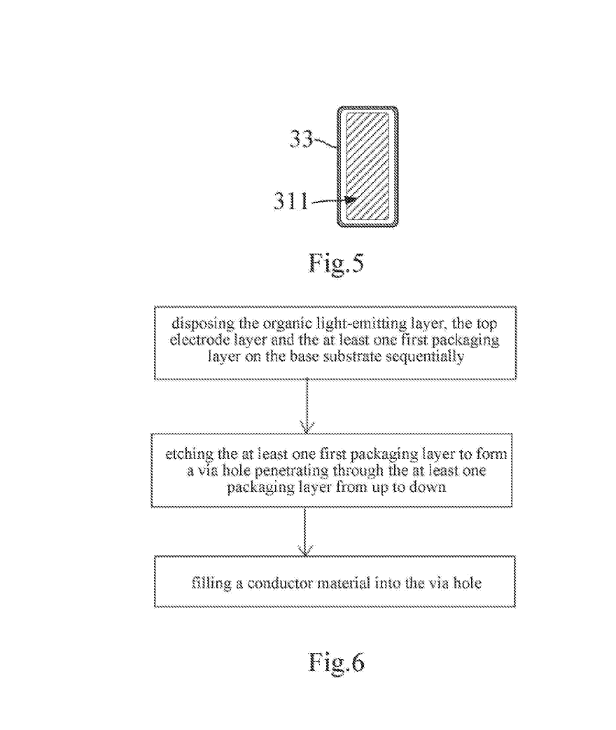

When the orthographic projection of the pattern of the auxiliary electrode layer 33 on the organic light-emitting layer 31 is located within the non-lighting region of the organic light-emitting layer 31, the auxiliary electrode layer 33 may still block the light on both sides of the organic light-emitting layer 31. This problem may be overcome by reducing a line width of the pattern of the auxiliary electrode layer 33. In another solution, as shown in FIG. 3, a distance between the auxiliary electrode layer 33 and the organic light-emitting layer 31 can also be reduced. As shown in FIG. 3, only one first packaging layer 40 is provided between the auxiliary electrode layer 33 and the top electrode layer 32, so that a height between the auxiliary electrode layer 33 and the organic light-emitting layer 31 is reduced, thereby reducing blocking of light on both sides of the organic light-emitting layer 31 caused by the auxiliary electrode layer 33. In a specific implementation, after forming one first packaging layer 40, via holes may be formed on the first packaging layer 40 and a pattern of the protective layer may be formed.

In order to further improve the packaging effect on the organic electroluminescent device, as shown in FIG. 3, in a specific implementation, two second packaging layers 60 are further disposed at the side of the auxiliary electrode layer 33 away from the base substrate. Specifically, the first packaging layer 40 in FIG. 3 is an inorganic film layer, and may be made of silicon nitride, silicon oxide, silicon oxynitride, silicon carbon nitride, aluminum oxide, etc., and may specifically be formed by an atomic layer deposition process, so that the thickness of the film layer is reduced and denser. One second packaging layer 60 at the side adjacent to the auxiliary electrode layer 33 can be used for planarization to better cover the auxiliary electrode layer, and the second packaging layer 60 may be an organic film layer and may also be an organic/inorganic composite film layer. Specifically, the inorganic film layer may be firstly manufactured to have protective properties, and then planarized by the organic film layer, and the manufacturing process thereof may be performed by coating, printing, CVD or evaporation. One second packaging layer 60 at the side away from the auxiliary electrode layer 33 is an inorganic film layer, of which the function is to further enhance the packaging effect. In the subsequent process, in order to achieve the protection of the second packaging layer 60, coating protective film layer or a sticking protective film may be coated thereon.

It should be noted that, in a specific implementation, the number of the second encapsulation layers 60 should be at least one, and may be set as other numbers such as three, four and the like, according to the required sealing performance requirements. The second packaging layer 60 may be made of an inorganic material, such as silicon nitride, silicon oxide, silicon oxynitride, silicon carbon nitride, aluminum oxide, etc., and may also be made of an organic material or an organic/inorganic composite material. Specifically, the second packaging layer 60 can be fabricated by an atomic layer deposition process to form a film layer having a low thickness and a denser density.

In summary, in the OLED display panel provided by the present disclosure, at least one pixel unit includes an organic electroluminescent device and an auxiliary electrode layer. The auxiliary electrode layer is connected with the top electrode layer to be commonly connected to the driving circuit, so that the resistance of the top electrode layer may be reduced to improve problems such as increased product power consumption and reduced display uniformity due to larger top electrode resistance of the organic electroluminescent device in the related art.

An embodiment of the present disclosure further provides a display device including any one of the above OLED display panels. The display device may be any product or component having a display function, such as a mobile phone, a tablet computer, a television, a display, a notebook computer, a digital photo frame, a navigator, and the like.

An embodiment of the present disclosure further provides a manufacturing method for an OLED display panel, the OLED display panel comprising: a base substrate 10 and a plurality of pixel units. The plurality of pixel units are disposed on the base substrate 10. The at least one pixel unit includes an organic electroluminescent device 30 and an auxiliary electrode layer 33, and the organic electroluminescent device 30 includes an organic light-emitting layer 31 and a top electrode layer 32 which are sequentially stacked on the base substrate 10. The auxiliary electrode layer 33 is disposed at a side of the top electrode layer 32 away from the base substrate 10, and is connected in parallel with the top electrode layer 32; at least one first packaging layer 40 is disposed between the auxiliary electrode layer 33 and the top electrode layer 32; and at least one via hole 42 is disposed in the first packaging layer 40. The specific manufacturing process is as follows:

sequentially disposing the organic light-emitting layer 31, the top electrode layer 32 and the at least one first package layer 40 on the base substrate 10, which process is well known to those skilled in the art and will not be described in detail;

etching the at least one first packaging layer 40 to form a via hole 42 that penetrates the first packaging layer 4 from up to down;

filling the via hole 42 with a conductor material.

In order to prevent etchants from damaging the top electrode layer 32, a protective layer 50 is disposed between the top electrode layer 32 and the first packaging layer 40. Specifically, the protective layer 50 is located between the top electrode layer 32 and the conductor within the via hole 42. The protective layer 50 includes two block electrodes, each of which is correspondingly connected with the conductor 02 within the via hole 42. In a specific implementation, the number of block electrodes should be arranged to correspond to that of via holes 42 in the packaging layer 40 in one-to-one correspondence. An area of each block electrode corresponding to the via hole 42 should be larger than the cross-sectional area of the corresponding via hole 42 to improve the protecting effect on the top electrode layer 32. In addition, in other implementations, the protective layer 50 may also take other shapes. Specifically, the pattern of the protective layer 50 includes at least one strip electrode, and each strip electrode is correspondingly connected with the conductor 02 within the at least one via hole 42. Thus, each strip electrode may be arranged to correspond to one or more via holes 42.

The display device provided by the embodiment can reduce the resistance of the top electrode layer, and improve problems such as increased product power consumption and reduced display uniformity due to larger top electrode resistance of the organic electroluminescent device in the related art.

It is apparent that those skilled in the art can make various modifications and variations to the embodiments of the present disclosure without departing from the spirit and scope of the present disclosure. Thus, it is intended that the present disclosure cover these modifications and variations which belong to the scope of the claims and its equivalent technical scope of the present disclosure.

What is claimed is:

1. An OLED display panel, comprising:
a base substrate;
a plurality of pixel units disposed on the base substrate;
at least one pixel unit comprising:
an organic electroluminescent device, comprising an organic light-emitting layer and a top electrode layer arranged to be sequentially stacked on the base substrate;
an auxiliary electrode layer disposed at a side of the top electrode layer away from the base substrate and connected with the top electrode layer in parallel.

2. The OLED display panel according to claim 1, wherein a top electrode signal line is provided on the base substrate, and the top electrode layer is connected with the top electrode signal line, the auxiliary electrode layer is connected with the top electrode signal line.

3. The OLED display panel according to claim 2, wherein at least one first packaging layer is provided between the auxiliary electrode layer and the top electrode layer.

4. The OLED display panel according to claim 3, wherein at least one via hole is provided on the at least one first packaging layer, and the auxiliary electrode layer is connected with the top electrode layer by a conductor disposed within the at least one via hole.

5. The OLED display panel according to claim 4, further comprising a protective layer disposed at a side of the top electrode layer away from the base substrate, in which a pattern of the protective layer is located between the top electrode layer and the conductor within the at least one via hole.

6. The OLED display panel according to claim 5, wherein the pattern of the protective layer comprises at least one strip electrode, each correspondingly connected with the conductor within at least one via hole; alternatively,
the pattern of the protective layer comprises at least one block electrode, each correspondingly connected with the conductor within a via hole;
wherein the protective layer is made of aluminum, indium tin oxide or zinc tin oxide.

7. The OLED display panel according to claim 3, wherein a via hole is provided on the at least one first packaging layer, and the auxiliary electrode layer is connected with the top electrode signal line by the conductor disposed within the via hole.

8. The OLED display panel according to claim 3, wherein the at least one first packaging layer comprises at least one organic film layer, or the at least one first packaging layer comprises at least one inorganic film layer, or, the at least one first packaging layer comprises at least one organic film layer and at least one inorganic film layer arranged to be sequentially overlapped.

9. The OLED display panel according to claim 3, wherein at least one second packaging layer is provided at a side of the auxiliary electrode layer away from the base substrate;
the at least one second packaging layer comprises at least one organic film layer, or, the at least one second packaging layer comprises at least one inorganic film layer, or, the at least one second packaging layer comprises at least one organic film layer and at least one inorganic film layer arranged to be sequentially overlapped.

10. The OLED display panel according to claim 9, wherein a first packaging layer is provided between the auxiliary electrode layer and the top electrode layer, two second packaging layers are provided at a side of the auxiliary electrode layer away from the base substrate;
the first packaging layer is an inorganic film layer;
one of the second packaging layers adjacent to a side of the auxiliary electrode layer is an organic film layer or an organic/inorganic composite film layer, one of the second packaging layers away from the side of the auxiliary electrode layer is an inorganic film layer.

11. The OLED display panel according to claim 3, wherein the auxiliary electrode layer is connected with the top electrode signal line by a conductive wire disposed on the at least one first packaging layer.

12. The OLED display panel according to claim 1, wherein at least one first packaging layer is provided between the auxiliary electrode layer and the top electrode layer, at least two via holes are provided on the first packaging layer, and the auxiliary electrode layer is connected with the top electrode layer by conductors disposed within the at least two via holes.

13. The OLED display panel according to claim 1, wherein an orthographic projection of the pattern of the auxiliary electrode layer on the base substrate is located in a non-lighting region.

14. The OLED display panel according to claim 13, wherein an orthographic projection of the pattern of the auxiliary electrode layer on the base substrate is located between orthographic projections of adjacent organic electroluminescent devices on the base substrate.

15. The OLED display panel according to claim 13, wherein, in a pixel unit comprising an organic electroluminescent device and an auxiliary electrode layer, an orthographic projection of the auxiliary electrode layer on the base substrate surrounds an orthographic projection of the organic electroluminescent device on the base substrate.

16. The OLED display panel according to claim 1, wherein a thickness of the auxiliary electrode layer is greater than a thickness of the top electrode layer.

17. A display device, comprising an OLED display panel, wherein the OLED display panel comprises:
a base substrate;
a plurality of pixel units disposed on the base substrate;
at least one pixel unit comprising:
an organic electroluminescent device comprising an organic light-emitting layer and a top electrode layer arranged to be sequentially stacked on the base substrate;
an auxiliary electrode layer disposed at a side of the top electrode layer away from the base substrate and connected with the top electrode layer in parallel.

18. The display device according to claim 17, wherein a top electrode signal line is provided on the base substrate, and the top electrode layer is connected with the top electrode signal line, the auxiliary electrode layer is connected with the top electrode signal line.

19. A manufacturing method of an OLED display panel, wherein the OLED display panel comprises:
a base substrate;
a plurality of pixel units disposed on the base substrate;
at least one pixel unit comprising:
an organic electroluminescent device comprising an organic light-emitting layer and a top electrode layer arranged to be sequentially stacked on the base substrate;
an auxiliary electrode layer disposed at a side of the top electrode layer away from the base substrate, and connected with the top electrode layer in parallel;
at least one first packaging layer provided between the auxiliary electrode layer and the top electrode layer; at least one via hole provided in the first packaging layer, wherein the manufacturing method comprises:
disposing the organic light-emitting layer, the top electrode layer and the at least one first packaging layer on the base substrate, sequentially;
etching the at least one first packaging layer to form a via hole penetrating through the at least one packaging layer from up to down; and
filling a conductor material into the via hole.

20. The manufacturing method of an OLED display panel according to claim 19, wherein a protective layer is disposed between the top electrode layer and the at least one packaging layer to prevent etchants from damaging the top electrode layer.
